(19) United States
(12) Patent Application Publication
(10) Pub. No.: US 2024/0203933 A1
(43) Pub. Date: Jun. 20, 2024

(54) ULTRASONIC COMPOSITE VIBRATION DEVICE AND MANUFACTURING APPARATUS OF SEMICONDUCTOR DEVICE

(71) Applicant: SHINKAWA LTD., Tokyo (JP)

(72) Inventors: Hikaru MIURA, Tokyo (JP); Takuya ASAMI, Tokyo (JP); Yoshihiro MIYATA, Tokyo (JP)

(73) Assignee: SHINKAWA LTD., Tokyo (JP)

(21) Appl. No.: 18/009,332

(22) PCT Filed: Jun. 17, 2021
(86) PCT No.: PCT/JP2021/023117

§ 371 Date: Dec. 9, 2022

(51) Int. Cl. H01L 23/00; B23K 20/00; B23K 20/10; B23K 101/40

(52) U.S. Cl. CPC H01L 24/78; B23K 20/005; B23K 20/10; B23K 2101/40; H01L 2224/78353

(57) ABSTRACT

An ultrasonic composite vibration device includes a base end part, an enlarged part, and a tip end part arranged in a straight line from a base end side to a tip end side. The base end part has a transducer generating longitudinal vibration and torsional vibration. The enlarged part has a cross-sectional area larger than the base end part, and the tip end part has a cross-sectional area smaller than the enlarged part. A node of the torsional vibration is located at the enlarged part, and antinodes of the longitudinal vibration and the torsional vibration are located at a base end surface and a tip end surface of the ultrasonic composite vibration device. An axial position and an axial dimension of the enlarged part are set to a position and a dimension at which resonance frequencies of the longitudinal vibration and the torsional vibration are substantially equal.

### TECHNICAL FIELD

This specification discloses an ultrasonic composite vibration device used in an ultrasonic processing machine for performing vibration processing (bonding, cutting, polishing, etc.) on a target object.

### RELATED ART

Conventionally, ultrasonic composite vibration devices have been proposed to generate longitudinal vibration and torsional vibration for performing vibration processing on a target object. However, in many of the conventional ultrasonic composite vibration devices, a resonance frequency of longitudinal vibration and a resonance frequency of torsional vibration are significantly different from each other, and it has not been possible to simultaneously generate two vibrations at one or similar frequencies.

Accordingly, in some ultrasonic composite vibration devices, it has also been proposed to generate longitudinal vibration and torsional vibration at one or similar frequencies. For example, Patent Document 1 has disclosed a technique of forming one ultrasonic composite device by combining a vibrating body having a stepped part and an electrostrictive transducer with a vibrating body having a stepped part and no vibrating element. It has been disclosed in Patent Document 1 that, by adjusting the distance from an antinode of the longitudinal vibration to the stepped part in each vibrating body, the resonance frequency of longitudinal vibration and the resonance frequency of torsional vibration are matched or approximated.

### RELATED ART DOCUMENTS

### Patent Document

Patent Document 1: Japanese Patent Application Laid-Open No. 2005-288351

### SUMMARY OF INVENTION

### Problem to be Solved by Invention

In Patent Document 1, the stepped part is adjusted to be the antinode of the torsional vibration. However, in general, it is difficult to use a stepped part as the antinode of the torsional vibration, partly because damping of vibration is likely to occur at the stepped part. Further, in Patent Document 1, two vibrating bodies are combined to form one ultrasonic composite device. Thus, since the ultrasonic composite device as a whole has two stepped parts and two joint surfaces of the vibrating bodies, its action is complicated, and it is difficult to adjust the dimensions and frequencies.

Accordingly, this specification discloses an ultrasonic composite device capable of generating longitudinal vibration and torsional vibration at one or similar frequencies while having a simplified configuration.

### Means for Solving Problem

An ultrasonic composite vibration device disclosed in this specification includes a base end part, an enlarged part, and a tip end part arranged in a straight line from a base end side to a tip end side. The base end part has a transducer that generates longitudinal vibration and torsional vibration. The enlarged part has a cross-sectional area larger than the base end part, and the tip end part has a cross-sectional area smaller than the enlarged part. A node of the torsional vibration is located at the enlarged part, and an antinode of the longitudinal vibration and an antinode of the torsional vibration are located at a base end surface and a tip end surface of the ultrasonic composite vibration device. An axial position and an axial dimension of the enlarged part are set to a position and a dimension at which a resonance frequency of the longitudinal vibration and a resonance frequency of the torsional vibration are substantially equal.

In this case, an axial dimension from an end surface of the enlarged part on the tip end side to an end surface of the tip end part on the tip end side may be an odd multiple of a ¼ wavelength of the torsional vibration.

Further, the tip end part may be formed with a slit in an inclined shape extending in a circumferential direction while progressing in an axial direction.

Further, a manufacturing apparatus of a semiconductor device disclosed in this specification includes the ultrasonic composite vibration device described above and a capillary. The capillary is attached to the tip end part, and a wire is inserted through the capillary. The transducer is driven at a drive frequency substantially equal to the resonance frequency of the longitudinal vibration and the resonance frequency of the torsional vibration.

### Effect of Invention

According to the techniques disclosed in this specification, it is possible to generate longitudinal vibration and torsional vibration at one or similar frequencies while having a simplified configuration.

### BRIEF DESCRIPTION OF DRAWINGS

FIG. 1 is a view showing a configuration of a manufacturing apparatus of a semiconductor device.

FIG. 2 is a perspective view of an ultrasonic composite vibration device that functions as an ultrasonic horn.

FIG. 3 is a side view of the ultrasonic composite vibration device and a diagram showing a waveform of vibration.

FIG. 4 is a graph showing a correlation between an axial dimension of an enlarged part and a resonance frequency.

FIG. 5 is a perspective view of another ultrasonic composite vibration device.

### DESCRIPTION OF EMBODIMENTS

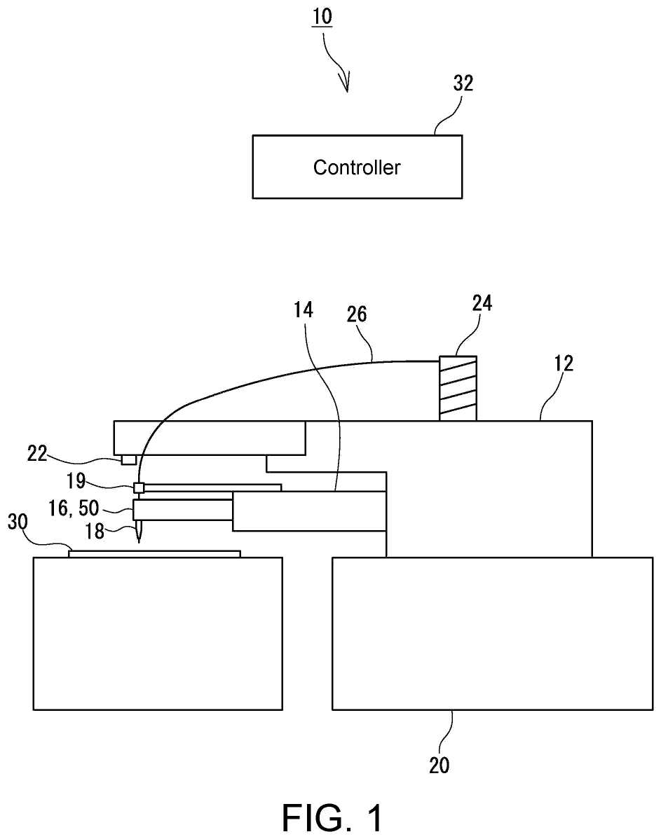

Hereinafter, configurations of an ultrasonic composite vibration device 50 and a manufacturing apparatus 10 of a semiconductor device equipped with the ultrasonic composite vibration device 50 will be described with reference to the drawings. FIG. 1 is a view showing the configuration of the manufacturing apparatus 10 equipped with the ultrasonic composite vibration device 50.

The manufacturing apparatus 10 is a wire bonding apparatus that manufactures a semiconductor device by connecting two electrodes provided on a target object 30 with a wire 26. The target object 30 is, for example, a lead frame on which a semiconductor chip is mounted. Generally, a semiconductor chip and a lead frame are respectively provided with electrodes, and by electrically connecting these electrodes with a wire 26, a semiconductor device is manufactured.

The manufacturing apparatus 10 has a bonding head 12 horizontally movable by an XY stage 20. An ultrasonic horn 16 and a camera 22 are attached to the bonding head 12 in a vertically movable manner. The ultrasonic horn 16 is attached to the bonding head 12 via a horn holder 14. The ultrasonic horn 16 is an ultrasonic composite vibration device 50 that generates longitudinal vibration and torsional vibration and transmits them to a capillary. The capillary 18 is a tubular member attached to a distal end of the ultrasonic horn 16 and through which the wire 26 is inserted. Longitudinal vibration and torsional vibration are transmitted to the wire 26 via this capillary 18. Furthermore, a clamper 19 that moves together with the capillary 18 and clamps the wire 26 is provided above the capillary 18.

The camera 22 captures an image of the target object 30 as required. Based on the image captured by the camera 22, a controller 32 identifies the position of the capillary 18 with respect to the target object 30 and positions the capillary 18. The bonding head 12 is further provided with a spool 24 around which the wire 26 is wound, and the wire 26 is let out from the spool 24 as required. The controller 32 controls the drive of each of the parts that constitute the manufacturing apparatus 10. For example, the controller 32 applies an AC voltage of a predetermined frequency to a transducer 58 provided in the ultrasonic horn 16 (i.e., the ultrasonic composite vibration device 50) to generate vibration of the predetermined frequency. Such a configuration of the manufacturing apparatus 10 is an example, and the ultrasonic composite vibration device 50, which will be described in detail later, may also be incorporated in a vibration processing machine of another configuration.

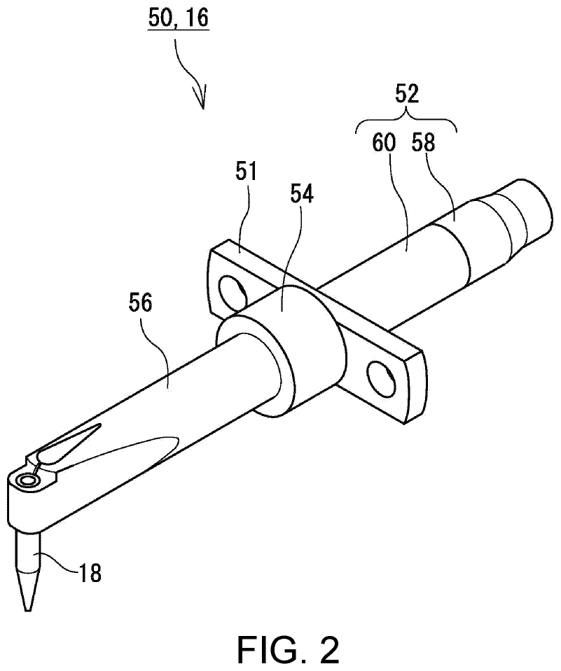

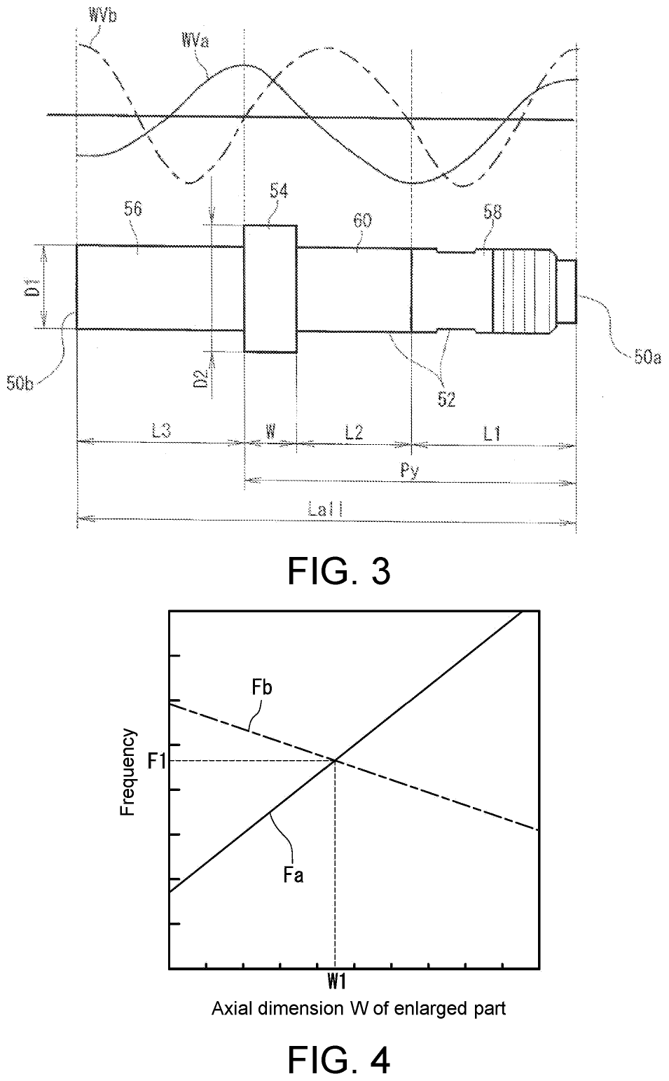

Next, the configuration of the ultrasonic composite vibration device 50 equipped on the manufacturing apparatus 10 will be described. FIG. 2 is a perspective view of the ultrasonic composite vibration device 50. FIG. 3 is a schematic side view of the ultrasonic composite vibration device 50. In the upper part of FIG. 3, a solid line WVa indicates the waveform of longitudinal vibration, and a dot-dashed line WVb indicates the waveform of torsional vibration. To simplify the description, in FIG. 3, the ultrasonic composite vibration device 50 is illustrated in a simplified manner. Thus, in FIG. 3, illustration of a mounting part of the capillary 18 and a flange 51 is omitted.

As described above, the ultrasonic composite vibration device 50 functions as the ultrasonic horn 16, and the capillary 18 is attached to a distal end of the ultrasonic composite vibration device 50. In this ultrasonic composite vibration device 50, a base end part 52, an enlarged part 54, and a tip end part 56 are arranged in a straight line from the base end side to the distal end side of the ultrasonic composite vibration device 50. The base end part 52 and the tip end part 56 are rod-shaped with substantially the same diameter. The base end part 52 is further substantially divided into a transducer 58 and a relay part 60 interposed between the transducer 58 and the enlarged part 54. The transducer 58 is a vibration source that receives a voltage signal and generates longitudinal vibration and torsional vibration. The transducer 58 is, for example, a bolt-clamped Langevin transducer (commonly called a BLT or BL transducer) having lead zirconate titanate (commonly called PZT) that vibrates upon receiving an AC voltage, in which the PZT is sandwiched by metal blocks and a clamping pressure is applied by a bolt. In addition to a PZT element that generates longitudinal vibration, the transducer 58 of this example also has a PZT element that generates torsional vibration by changing the polarization direction. Thus, the transducer 58 can generate both longitudinal vibration and torsional vibration.

The enlarged part 54 is a portion having a larger diameter than the base end part 52 and the tip end part 56. A diameter D2 of the enlarged part 54 is not particularly limited as long as it is larger than a diameter D1 of the tip end part 56. However, the greater the diameter D2 of the enlarged part 54, the greater the damping effect of torsional vibration, and the more likely it is for the enlarged part 54 to become a node of the torsional vibration. Thus, the diameter D2 of the enlarged part 54 may be, for example, 1.5 times or more the diameter D1 of the tip end part 56. In addition, an axial dimension W of the enlarged part 54 is set so that a resonance frequency Fa of longitudinal vibration and a resonance frequency Fb of torsional vibration match or are close to each other, which will be described later. A flange 51 is provided between the enlarged part 54 and the relay part 60. This flange 51 is used when attaching the ultrasonic composite vibration device 50 to the horn holder 14.

The tip end part 56 is rod-shaped with substantially the same diameter as the base end part 52, and the capillary 18 is attached to the distal end of the tip end part 56. An axial dimension L3 of the tip end part 56 is not particularly limited, but the axial dimension L3 is generally substantially equal to an odd multiple of ¼ wavelength of torsional vibration. This is because a wavelength Ab and a phase of the torsional vibration generated at the tip end part 56 are automatically adjusted so that the enlarged part 54 becomes the node of the torsional vibration and the distal end of the tip end part 56 becomes the antinode of the torsional vibration. Thus, when the wavelength of the torsional vibration is λb, L3≈λb/4×(2n+1). Furthermore, as shown in the upper part of FIG. 3, in this example, respective wavelengths λa and λb are set so that antinodes of longitudinal vibration and torsional vibration are positioned at a base end surface 50a and a tip end surface 50b of the ultrasonic composite vibration device 50.

Next, the setting of the axial dimension W of the enlarged part 54 and a drive frequency F1 of the transducer 58 will be described. When an axial dimension L1 of the transducer 58, an axial dimension L2 of the relay part 60, and an axial dimension Lall of the ultrasonic composite vibration device 50 are constant, by changing the axial dimension W of the enlarged part 54, the natural frequency of the ultrasonic composite vibration device 50 is changed, and the resonance frequency Fa of longitudinal vibration and the resonance frequency Fb of torsional vibration are changed. FIG. 4 is a graph showing a correlation between the axial dimension W of the enlarged part 54 and the resonance frequencies Fa and Fb. In FIG. 4, the horizontal axis indicates the axial dimension W of the enlarged part 54, and the vertical axis indicates the resonance frequency. In FIG. 4, a solid line indicates the resonance frequency Fa of longitudinal vibration, and a dot-dashed line indicates the resonance frequency Fb of torsional vibration.

In the example of FIG. 4, the resonance frequency Fa of longitudinal vibration decreases in proportion to the increase in the axial dimension W. On the other hand, the resonance frequency Fb of torsional vibration increases in proportion to the increase in the axial dimension W. When the axial dimension W is a predetermined value W1, the resonance frequency Fa of longitudinal vibration and the resonance frequency Fb of torsional vibration match, and Fa=Fb=F1.

In this example, the axial dimension W of the enlarged part 54 is the axial dimension W1 at the time of Fa=Fb=F1. That is, W=W1. Further, when the ultrasonic composite vibration device 50 is driven, the frequency of the AC voltage applied to the transducer 58, i.e., the drive frequency, is set to F1. Accordingly, the resonance of longitudinal vibration and torsional vibration can be generated at one frequency F1, and the drive control of the ultrasonic composite vibration device 50 can be simplified.

Although FIG. 4 shows an example in which the resonance frequencies Fa and Fb are proportional to the axial dimension W, the correlation between the resonance frequencies Fa and Fb and the axial dimension W varies as appropriate according to the shape and material of the ultrasonic composite vibration device 50, the characteristics of the transducer 58, etc. Thus, the axial dimension W and the drive frequency F1 are specified by experiments or simulations in the design stage of the ultrasonic composite vibration device 50.

In this example, since the tip end of the ultrasonic composite vibration device 50 is the antinodes of longitudinal vibration and torsional vibration, large longitudinal vibration and torsional vibration can be obtained at the tip end of the ultrasonic composite vibration device 50. i.e., at the mounting part of the capillary 18. As a result, the capillary 18 can be ultrasonically vibrated planarly, and the processing efficiency of wire bonding can be improved.

In the description thus far, the drive frequency F1, at which Fa=Fb=F1, is specified by changing the values of W and L3=Wall-L1-L2-W. However, the resonance frequencies Fa and Fb change not only with the axial dimension W of the enlarged part 54 but also with the axial position of the enlarged part 54. Thus, the axial position of the enlarged part 54 may also be changed to specify the drive frequency F1.

For example, the following case is considered: the distance from the base end surface 50a of the ultrasonic composite vibration device 50 to a tip end side surface of the enlarged part 54 is Py, and the axial dimension L1 of the transducer 58, the axial dimension Lall of the ultrasonic composite vibration device 50, and the axial dimension W of the enlarged part 54 are kept constant. In this case, the axial dimension L2 of the relay part 60 is L2=Py-W-L1, and the axial dimension L3 of the tip end part 56 is L3=Lall-Py. That is, the axial dimensions L2 and L3 of the relay part 60 and the tip end part 56 change according to the axial position Py of the enlarged part 54. By changing these dimensions L2 and L3, the natural frequency of the ultrasonic composite vibration device 50 changes, and the resonance frequencies Fa and Fb change. Thus, when designing the ultrasonic composite vibration device 50, instead of the axial dimension W of the enlarged part 54, the axial position Py of the enlarged part 54 may be changed to specify an appropriate position of the enlarged part 54 and the drive frequency F1. In this case, the value of the axial dimension W of the enlarged part 54 is not particularly limited, but may be, for example, about ¼ times the wavelength λb of torsional vibration. That is, W≈λb/4 may be set.

In any case, in this example, only one enlarged part 54 is provided in the ultrasonic composite vibration device 50. Thus, it is possible to reduce the number of parameters to be changed to specify the drive frequency F1=Fa=Fb. As a result, the optimum dimensions and drive frequency of the ultrasonic composite vibration device 50 can be easily specified.

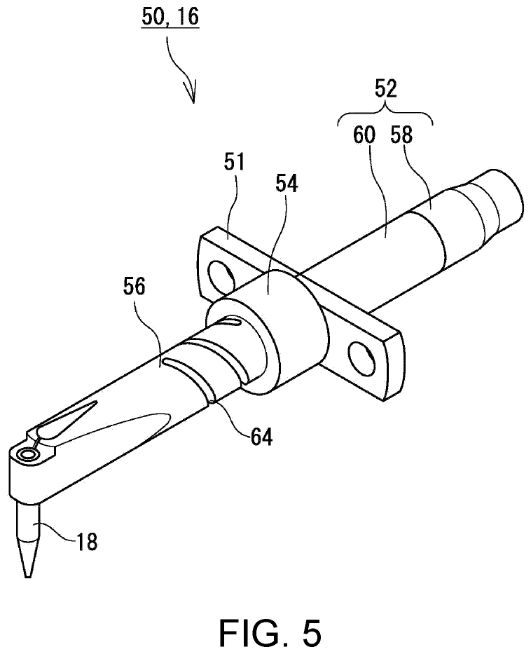

Further, in the description thus far, the longitudinal vibration generated by the transducer 58 is transmitted as longitudinal vibration as it is to the tip end. However, the tip end part 56 may also be provided with a vibration converting part that converts part of the longitudinal vibration into torsional vibration. For example, as shown in FIG. 5, a slit 64 in an inclined shape extending in a circumferential direction while progressing in the axial direction may be provided in a peripheral surface of the tip end part 56 to convert part of the longitudinal vibration into torsional vibration. By adopting such a configuration, it is possible to more reliably apply torsional vibration to the distal end of the tip end part 56 and thus to the capillary 18. Also, the cross-sectional shape of the ultrasonic composite vibration device 50 is not limited to a circle, but may also be another shape such as a rectangle.

In addition, in the description thus far, the ultrasonic composite vibration device 50 is incorporated into a wire bonding apparatus. However, the ultrasonic composite vibration device 50 disclosed in this specification is not limited to a wire bonding apparatus, but may also be incorporated into another ultrasonic processing machine such as an ultrasonic welding apparatus.

### REFERENCE SIGNS LIST

10 manufacturing apparatus; 12 bonding head; 14 horn holder; 16 ultrasonic horn, 18 capillary; 19 clamper; 20 XY stage; 22 camera; 24 spool; 26 wire; 30 target object; 32 controller; 50 ultrasonic composite vibration device; 52 base end part; 54 enlarged part; 56 tip end part; 58 transducer; 60 relay part; 64 slit

1. An ultrasonic composite vibration device, comprising a base end part, an enlarged part, and a tip end part arranged in a straight line from a base end side to a tip end side, wherein
the base end part has a transducer that generates longitudinal vibration and torsional vibration,
the enlarged part has a cross-sectional area larger than the base end part, and the tip end part has a cross-sectional area smaller than the enlarged part,
a node of the torsional vibration is located at the enlarged part, and an antinode of the longitudinal vibration and an antinode of the torsional vibration are located at a base end surface and a tip end surface of the ultrasonic composite vibration device, and
an axial position and an axial dimension of the enlarged part are set to a position and a dimension at which a resonance frequency of the longitudinal vibration and a resonance frequency of the torsional vibration are substantially equal.

2. The ultrasonic composite vibration device according to claim 1, wherein
an axial dimension from an end surface of the enlarged part on the tip end side to an end surface of the tip end part on the tip end side is an odd multiple of a ¼ wavelength of the torsional vibration.

3. The ultrasonic composite vibration device according to claim 1, wherein
the tip end part is formed with a slit in an inclined shape extending in a circumferential direction while progressing in an axial direction.

4. A manufacturing apparatus of a semiconductor device, comprising:
the ultrasonic composite vibration device according to claim 1; and
a capillary attached to the tip end part, a wire being inserted through the capillary,
wherein the transducer is driven at a drive frequency substantially equal to the resonance frequency of the longitudinal vibration and the resonance frequency of the torsional vibration.
